(19) United States
(12) Patent Application Publication
(10) Pub. No.: US 2012/0020157 A1
(43) Pub. Date: Jan. 26, 2012

(54) Novel high-temperature non-volatile memory design

(75) Inventors: Peter Wung Lee, Saratoga, CA (US); Fu-Chang Hsu, San Jose, CA (US)

(73) Assignee: Aplus Flash Technology, Inc.

(21) Appl. No.: 13/136,045

(22) Filed: Jul. 21, 2011

Related U.S. Application Data
(60) Provisional application No. 61/400,113, filed on Jul. 21, 2010.

(51) Int. Cl. G11C 16/04; H01L 29/78; H01L 21/336

(52) U.S. Cl. 365/185.05; 438/294; 257/367; 257/E29.255; 257/E21.409

(57) ABSTRACT

A method for fabricating a high temperature integrated circuit includes forming a drain/source diffusion and forming a buried diffusion implant containing the drain/source diffusion in a substrate to separate the drain/source diffusion from the substrate and an edge of a field isolation layer to decreases leakage current occurring with high voltage and high temperature. A nonvolatile memory array driver circuit with multiple driver transistors separated by anti-leakage transistors connected to prevent excess junction leakage current at elevated temperatures. Another nonvolatile memory array driver circuit has a high voltage blocking transistor connected to two anti-leakage transistors connected such that a source of the first anti-leakage transistor is connected to a drain of the high voltage blocking transistor and a drain of the second anti-leakage transistor is connected to prevent excess junction leakage current at elevated temperatures.

This application claims priority under 35 U.S.C. §119 to U.S. Provisional Patent Application U.S. Provisional Patent Application Ser. No. 61/400,113, filed on Jul. 21, 2010, assigned to the same assignee as the present invention, and incorporated herein by reference in its entirety.

### BACKGROUND OF THE INVENTION

1. Field of the Invention

This invention relates generally to memory circuits and integrated circuit processes for fabricating memory circuits. More particularly, this invention relates to nonvolatile memory circuits and integrated processes for fabricating nonvolatile memory circuits capable of operation at high temperatures with low leakage currents.

2. Description of Related Art

In applications for automotive and military environments, integrated electronic circuits must be capable of operating in a high-temperature environment. The integrated electronic circuits must operate with no failure or decrease in operational specifications at an upper temperature of +85° C. according to standard industry temperature specifications. In automotive or military applications, the upper temperature limit is specified to be +125° C.

Non-Volatile-Memory includes One-Time-Programmable Read Only Memory (OTP ROM), Electrically Eraseable Programmable Read Only Memory (EEPROM), and Flash nonvolatile memory as well known in the art. Programmable and Eraseable nonvolatile memory in the prior art includes circuits that must endure high voltages applied to their elements. Examples of the circuits are charge-pumps, column-decoders, row-decoders, page-buffers and the memory cell array. Each of these circuits are designed to supply the desired positive or negative high-voltage levels from a low-voltage power supply voltage source (VDD) to perform the desired on-chip program and erase operations without external high voltage power supply pins.

As is known in the art, the current through a junction between a P-type and an N-type semiconductor material is dependent upon temperature and is determined by the formula of the ideal diode law:

I=I_{S}(e^{VD/nVT}−1)

Where:
I is the diode current,
I_{S} is the reverse bias saturation current (or scale current) that is dependent upon donor and acceptor concentrations at the native of the junction
V_{D} is the voltage across the diode,
V_{T} is the voltage equivalent of temperature where:

$${V}_{T} = \frac{kT}{q}$$

where:
k is Boltzmann's Constant,
T is the absolute temperature of the P-N junction, and
q is the magnitude of the charge of an electron, and
n is the ideality factor, also known as the quality factor or sometimes emission coefficient.

It can be shown that the reverse leakage current or junction leakage current increases exponentially with temperature increase. The junction in this instance is a parasitic bipolar junction between the high voltage NMOS transistor source and drain junctions and the common bulk of the P-substrate or the triple p-well formed within a deep N-well over the common bulk of the P-substrate in the triple P-well structure.

“Local Oxidation of Silicon for Isolation”, P. Smeys, chapter 2, PhD Thesis, 2000, Stanford University, found Jul. 6, 2011, www.stanford.edu/class/ee311/NOTES/isolationSmeys.pdf, found Jul. 6, 2011, provides an overview of isolation technologies, particularly conventional local oxidation of silicon (LOCOS) structure. Smeys further illustrates three current leakage paths; between two neighboring devices in the same well, junction to well leakage, and latch-up triggering.

“Contribution of gate induced drain leakage to overall leakage and yield loss in digital submicron VLSI circuits,” Semenov, et al., IEEE International Integrated Reliability Workshop Final Report, 2001, October, 2001, pp. 49-53, Found: www.ieeexplore.ieee.org/stamp/stamp.jsp?tp=&arnumber=993916&isnumber=21443, Jul. 6, 2011, and “Impact of gate induced drain leakage on overall leakage of sub-micrometer CMOS VLSI circuits,” Semenov, et al., IEEE Transactions on Semiconductor Manufacturing, Vol. 15, No. 1, pp. 9-18, February 2002, found www.ieeexplore.ieee.org/stamp/stamp.jsp?tp=&arnumber=983439&isnumber=21193, Found: Jul. 6, 2011, discuss the impact of gate induced drain leakage (GIDL) on the overall leakage of sub-micrometer VLSI circuits. GIDL constitutes a serious constraint, with regards to off-state current, in scaled down complimentary metal-oxide-semiconductor (CMOS) devices for DRAM and/or EEPROM applications and scaled CMOS digital VLSI circuits. Experimental and simulation data of GIDL current as a function of 0.35-μm CMOS technology parameters and layout of CMOS standard cells is presented.

Study has revealed that, at a higher temperature environment, the higher leakage current happens at all edges of PN parasitic junctions rather than at the overlapping PN junction areas. The edge of the PN parasitic junctions between the substrate and the sources and drains of the high voltage transistors of nonvolatile memory devices at an edge of a LOCOS field oxide multiplies a junction leakage current effect. This can be reduced by process improvement but at the sacrifice of the lower junction breakdown voltage, which is against the required high voltage specifications for proper on-chip program and erase operation of the nonvolatile memory. The reason for the higher leakage current at the distributive edges of the parasitic bipolar junction between the high voltage NMOS transistor source and drain junctions and the common bulk of the P-substrate or the triple p-well is because the much higher P-type implant at edges for the commonly used technique to have the safe field isolation between any two adjacent HV NMOS devices. These critical temperature-sensitive edges of the devices of the parasitic bipolar junctions between the high voltage NMOS transistor source and drain junctions and the common bulk of the P-substrate or the triple P-well are distributed everywhere in the high voltage areas of the nonvolatile memory integrated circuits.

### SUMMARY OF THE INVENTION

An object of this invention is to provide nonvolatile memory driver circuits for minimizing leakage current resulting from operating a nonvolatile memory at elevated temperatures.

Another object of this invention is to provide a method for fabricating a nonvolatile memory array for minimizing leakage current resulting from operating a nonvolatile memory at elevated temperatures.

To accomplish at least one of these objects, in some embodiments a method for fabricating a high temperature integrated circuit includes forming a drain/source diffusion of a first conductivity type separate from a substrate and an edge of a field isolation layer such that a concentration of impurity at the edge of the field isolation layer decreases a leakage occurring with high voltage and high temperature applied to the source/drain diffusion.

In various embodiments of a nonvolatile memory array driver circuit has multiple driver transistors. Each of the multiple driver transistors has its drain connected to a high voltage distribution conductor and its source connected to the nonvolatile memory array. A gate of each of the multiple driver transistors is connected to a select circuit for choosing at least one of the multiple driver transistors for activation. Multiple anti-leakage transistors are placed between adjacent driver transistors such that each of the anti-leakage transistors has a drain connected to the source of one driver transistor of the multiple driver transistors and a source connected to an adjacent driver transistor. A gate of the anti-leakage transistors is connected to a biasing voltage source to bias the anti-leakage transistor to prevent excess junction leakage current at elevated temperatures at the edges of the parasitic PN-junctions of the driver transistors.

A buried implant layer between the drain/source diffusion and the field isolation layer and the substrate to separate the drain/source diffusion from the substrate and the field isolation layer. A concentration of an implanted impurity species material of the drain/source is 1×10¹⁵ charges/cm³ and the concentration of the first buried implant region is 1×10¹⁴ charges/cm³ such that the lower concentration at the parasitic PN junction of the buried implant diffusion layer decreases the reverse leakage current at an elevated temperature.

In other embodiments, a nonvolatile memory array driver circuit has a high voltage blocking transistor having a drain connected to a driver transistor and to a terminal connected to the memory array. A source of the high voltage blocking transistor is connected to a low voltage switching circuit for connecting an output terminal of the nonvolatile memory array driver circuit to a reference voltage level. A gate of the high voltage blocking transistor is connected to a power supply voltage source to bias the high voltage blocking transistor to a voltage level no greater than the voltage level of the power supply voltage source less a threshold voltage level of the high voltage blocking transistor when a high voltage level is applied to the output terminal. The nonvolatile memory array driver circuit further has two anti-leakage transistors connected such that a source of the first anti-leakage transistor is connected to a drain of the high voltage blocking transistor and a drain of the second anti-leakage transistor is connected to a source of the high voltage blocking transistor. A drain of the first anti-leakage transistor and a source of the second anti-leakage transistor are floating. The gates of the first and second anti-leakage transistors are connected to the power supply voltage source. The two anti-leakage transistors prevent excess junction leakage current at elevated temperatures at the edges of the parasitic PN-junctions of the driver transistors.

The memory array driver circuit is a charge-pump, column-decoder, row-decoder, page-buffer or the memory cell array that requires a high voltage for programming or erasing the nonvolatile memory circuit.

In still other embodiments, the nonvolatile memory cell includes a select transistor with a drain region of a first conductivity type implanted in a substrate and connected to communicate to a bit line. The drain region is placed above a buried implant region that prevents junction leakage current at elevated temperatures at the edges of a parasitic PN-junction of the drain region in proximity to field isolation regions bordering the nonvolatile memory cell.

In various embodiments, the nonvolatile memory cell includes a source region of the first conductivity type implanted in a substrate and connected to communicate to a source line that is in parallel with the bit line. The source region is above by a second buried implant that prevents excess junction leakage current at elevated temperatures at the edges of a parasitic PN-junction of the source region in proximity to field isolation regions bordering the nonvolatile memory cell.

The concentration of the implanted impurity species material of the drain of the select transistor is 1×10¹⁵ charges/cm³ and the concentration of the first buried implant region is 1×10¹⁴ charges/cm³ such that the lower concentration at the parasitic PN junction of the buried implant diffusion layer decreases the reverse leakage current at an elevated temperature. Similarly, the concentration of an implanted impurity species material of the source of the FLOTOX EEPROM transistor is 1×10¹⁵ charges/cm³ and the concentration of the second buried implant region is 1×10¹⁴ charges/cm³ such that the lower concentration at the parasitic PN junction of the second buried implant diffusion layer decreases the reverse leakage current at an elevated temperature.

In some embodiments, a method for fabricating a nonvolatile memory cell includes forming a drain region of a first conductivity type implanted in a substrate. The drain region is connected to communicate with a bit line. Prior to forming the drain region a buried implant is diffused into the substrate beneath the location of the drain region to prevent excess junction leakage current at elevated temperatures at the edges of a parasitic PN-junction of the drain region in proximity to field isolation regions bordering the nonvolatile memory cell.

In various embodiments, the method for fabricating the nonvolatile memory cell includes implanting a source region of the first conductivity type in the substrate. The source region connected to communicate to a source line that is in parallel with the bit line. Prior to forming the source region a second buried implant is diffused into the substrate beneath the location of the source region to prevent excess junction leakage current at elevated temperatures at the edges of a parasitic PN-junction of the drain region in proximity to field isolation regions bordering the nonvolatile memory cell.

### BRIEF DESCRIPTION OF THE DRAWINGS

FIG. 1a illustrates the schematic circuit for a 2-transistor, FLOTOX EEPROM cell of the prior art.

FIGS. 1b and 1c are respectively a top view and a cross sectional view that illustrate the physical layout for the two-transistor FLOTOX EEPROM cell of FIG. 1a of a two-transistor FLOTOX EEPROM cell as formed in a substrate of the prior art.

FIG. 1d is a cross sectional view of the drain of the select transistor of the FLOTOX EEPROM cell of FIG. 1a of the prior art.

FIG. 2a is a schematic diagram of a two-byte section of an array of FLOTOX EEPROM cells of the prior art.

FIG. 2b is a diagram of a top view of the two-byte section of the array of FLOTOX EEPROM cells of FIG. 2a of the prior art showing the control gate biasing select transistors.

FIG. 2c is a diagram illustrating a cross section of control gate biasing select transistors of the two-byte section of the array of FLOTOX EEPROM cells of FIG. 2a of the prior art.

FIG. 3 is a schematic diagram of a word line driver circuit of a row-decoder circuit of the prior art.

FIGS. 4a and 4b are respectively a top view and a cross sectional view that illustrate the physical layout for various embodiments of a two-transistor FLOTOX EEPROM cell as formed in a substrate embodying the principles of the present invention.

FIG. 4c is a cross sectional view of the drain of the select transistor for some embodiments of the FLOTOX EEPROM cell of FIGS. 4a and 4b embodying the principles of the present invention.

FIG. 5a is a schematic diagram of various embodiments of a two-byte section of an array of FLOTOX EEPROM cells embodying the principles of the present invention.

FIG. 5b is a diagram of a top view of the various embodiments of the two-byte section of the array of FLOTOX EEPROM cells of FIG. 5a embodying the principles of the present invention.

FIG. 5c is a diagram illustrating a cross section of the various embodiments of control gate biasing select transistors with the anti-leakage transistors of the two-byte section portion of the array of FLOTOX EEPROM cells of FIGS. 5a and 5b embodying the principles of the present invention.

FIGS. 6a and 6b are respectively a top view and a cross sectional view that illustrate the physical layout for various embodiments of a two-transistor FLOTOX EEPROM cell as formed in a substrate embodying the principles of the present invention.

FIG. 6c is a cross sectional view of the drain of the select transistor for the embodiments of the FLOTOX EEPROM cell of FIGS. 6a and 6b embodying the principles of the present invention.

FIG. 6d is a cross sectional view of the source of the FLOTOX EEPROM transistor for the embodiments of the FLOTOX EEPROM cell of FIGS. 6a and 6b embodying the principles of the present invention.

FIG. 7a is a schematic diagram of various embodiments of a two-byte section of an array of FLOTOX EEPROM cells embodying the principles of the present invention.

FIG. 7b is a diagram of a top view of the various embodiments of the two-byte section of the array of FLOTOX EEPROM cells of FIG. 5a embodying the principles of the present invention.

FIG. 8 is a schematic diagram of a word line driver circuit of a row-decoder circuit embodying the principles of the present invention.

FIG. 9 is a flow diagram for a method of fabricating embodiments of an array of two-transistor FLOTOX EEPROM cells formed in a substrate embodying the principles of the present invention.

### DETAILED DESCRIPTION OF THE INVENTION

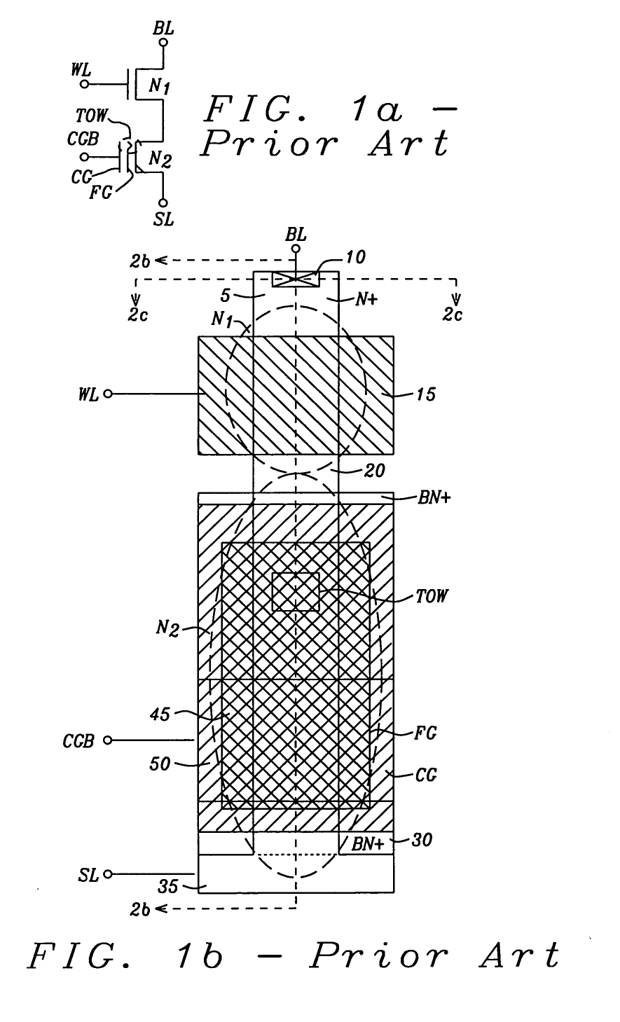

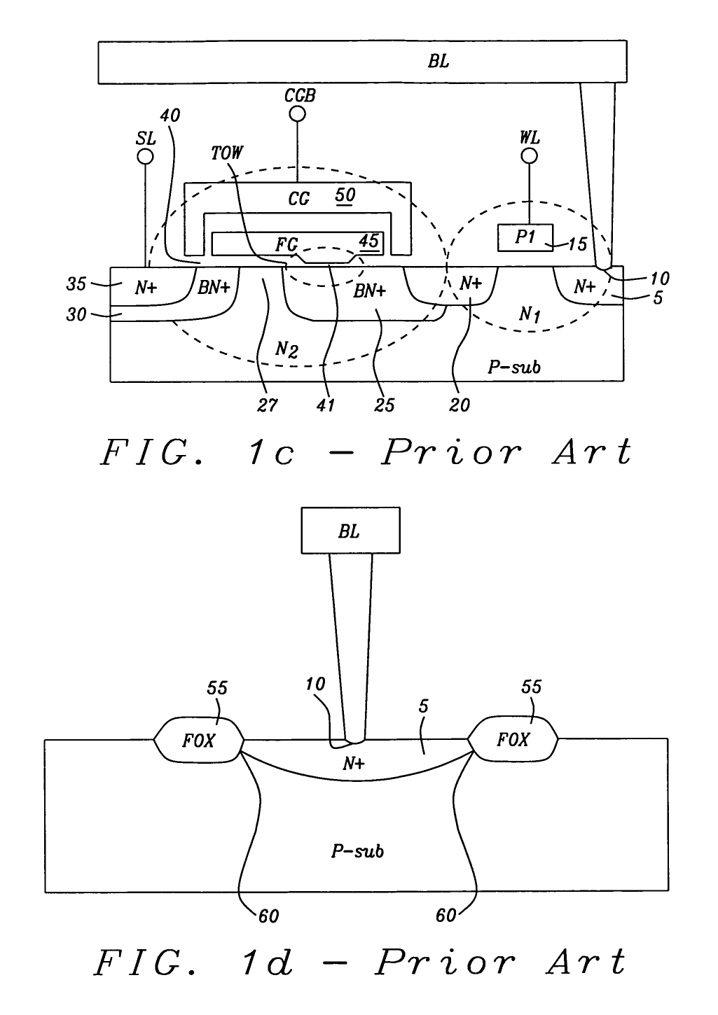

FIG. 1a illustrates the schematic circuit for a 2-transistor FLOTOX EEPROM cell of the prior art. The EEPROM cell of the prior art includes of two transistors N₁ and N₂. The select transistor, N₁ is a polycrystalline silicon (polysilicon) NMOS device with its gate connected to a select gate signal SG. The source of the select transistor N₁ is connected to the drain of the floating gate tunnel oxide (FLOTOX) EEPROM transistor N₂. The FLOTOX EEPROM transistor N₂ is a double polysilicon floating gate device. A first layer of polysilicon is the floating-gate FG that is used to store the charges representing the binary “0” and binary “1” of the stored data. The second layer of the polysilicon is a control gate CG that is connected to the word line WL. The drain of the select transistor N₁ is connected to a vertical metal bit line BL. The source of the EEPROM transistor N₂ is connected to a common horizontal implanted source line SL.

FIGS. 1b and 1c illustrate the physical layout for the two-transistor FLOTOX EEPROM cell of FIG. 1a of the traditional two-transistor FLOTOX EEPROM cell as formed in a substrate P-sub. A first layer polysilicon conductor 15 forms the select gate SG and runs horizontally to form the select gate SG of adjacent FLOTOX EEPROM cells and forms the word line WL. The overlapping area of a first layer polysilicon conductor 15 and N⁺ active layers 5 (drain) and 20 (source) form the polysilicon NMOS select transistor N₁. The drain region 5 of the select transistor N₁ has a half-contact 10 for the connection with the global metal bit line BL. The FLOTOX EEPROM transistor N₂ is a double-poly floating gate device and is formed above the N⁺ layers 20 and 35 and the buried implant layers BN+ 25 and 30. The first layer polysilicon conductor 45 forms the floating gate FG and is placed below the second layer polysilicon conductor 50 that forms the control gate CG. A square box of a tunnel oxide window layer TOW is a region 41 of the gate oxide 40 that is thinned to about 100 Å thickness to allow Fowler-Nordheim programming and erasing during the normal write operation of the FLOTOX EEPROM transistor N₂. The source of the FLOTOX EEPROM cell N₂ is formed of the buried implant layer BN+ 30 and the N+ implant 35. The N+ implant 35 is a horizontal implant that forms the common source line SL for each of the FLOTOX EEPROM transistors N₂ of a row of FLOTOX EEPROM cells.

The control gate CG is connected to a control gate biasing voltage line CGB that provides the necessary voltages to the control gate CG for programming, erasing, and reading the data from the FLOTOX EEPROM cell.

FIG. 1d is a cross sectional view of the drain of the select gate of the FLOTOX EEPROM cell of FIG. 1a. The N+ implant 5 that forms the drain of the select gate N₁ is bounded by the field oxide isolation layers 55. In the formation of the drain of the select gate N₁, the field oxide isolation layers 55 are self-aligning features that to precisely define the drain of the select gate N₁. The contact metallurgy 10 provides the connection from the drain of the select gate N₁ to the metal bit line BL. As described in Smeys and Semenov, the leakage current at high temperatures occurs at the edges of the PN junction of the substrate P-sub and the N+ implant 5 at the boundary of the field oxide isolation layers 55.

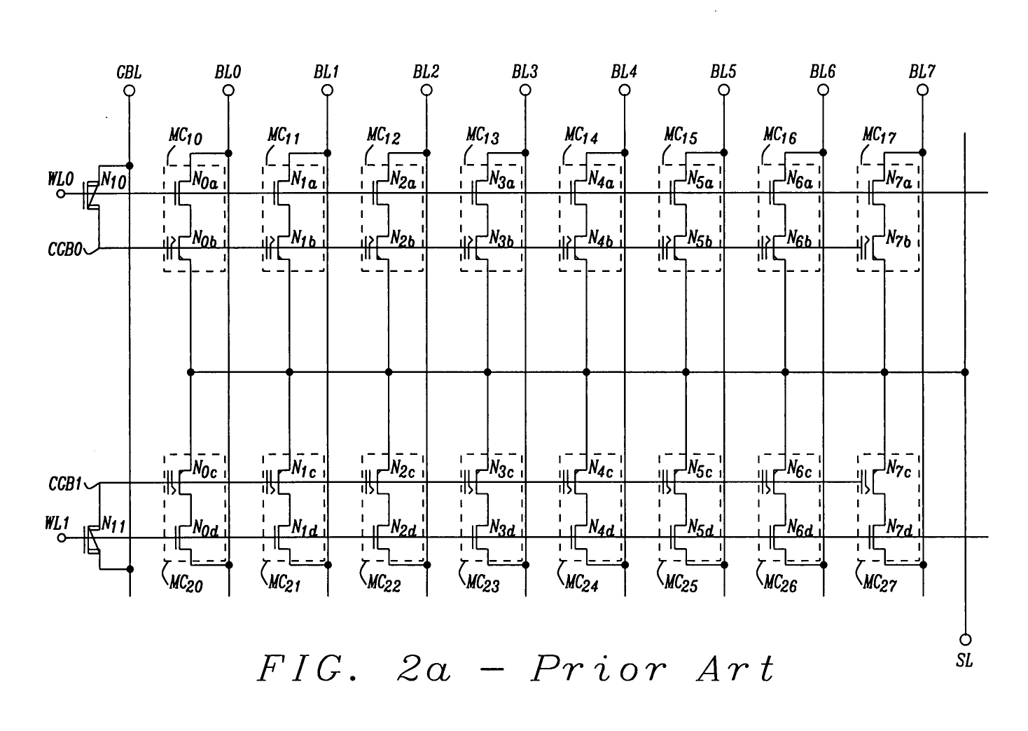

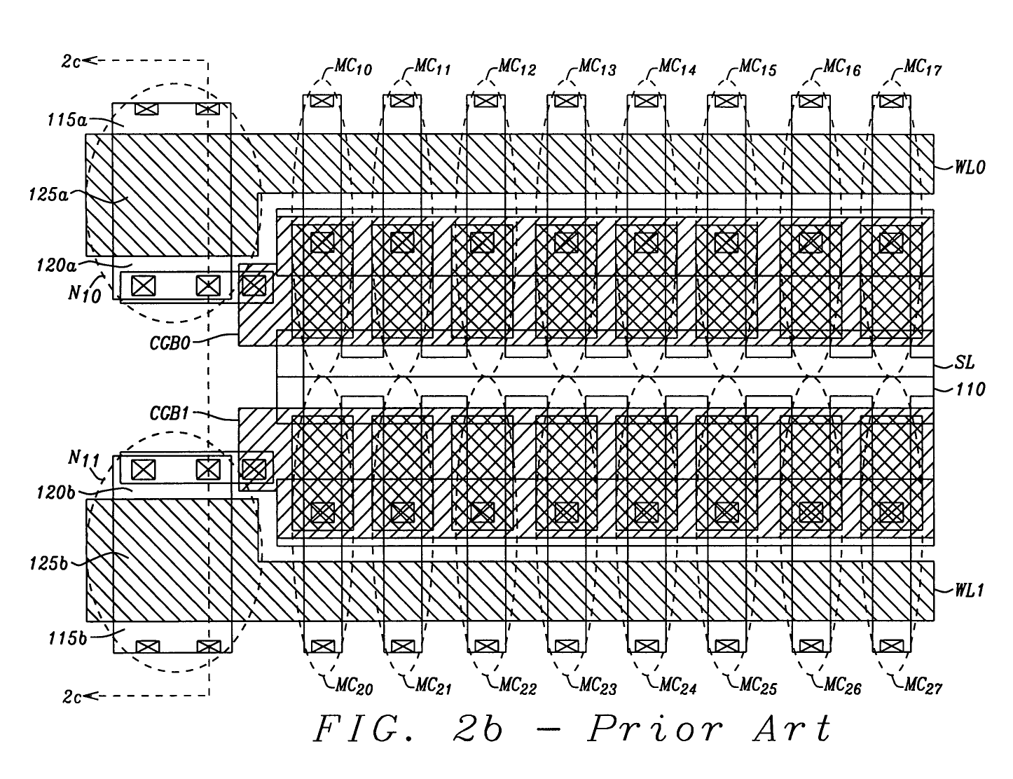

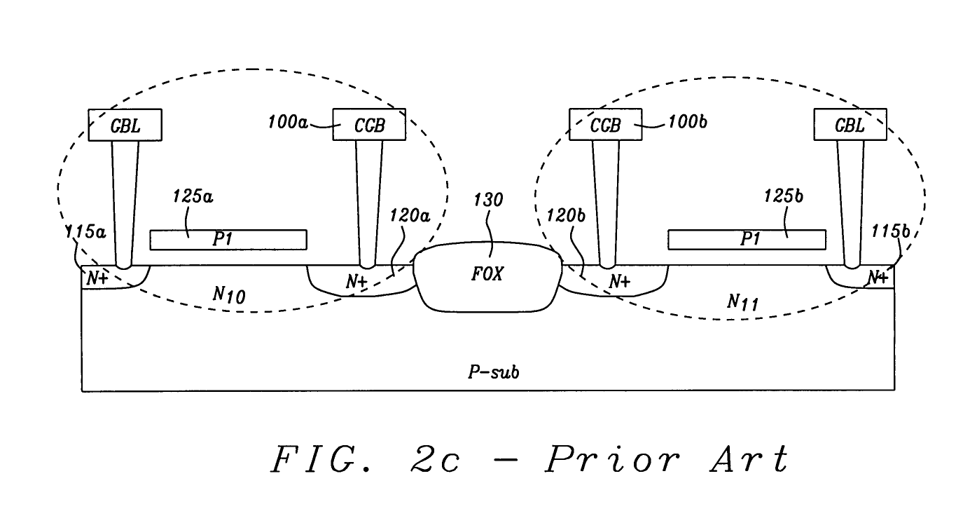

FIG. 2a is a schematic diagram of a portion of an array of FLOTOX EEPROM cells of the prior art. FIG. 2b is a diagram of a top view of the portion of the array of FLOTOX EEPROM cells of FIG. 2a of the prior art. FIG. 2c is a diagram illustrating a cross section of control gate biasing select transistors N10 and N11 the portion of the array of FLOTOX EEPROM cells of FIG. 2a of the prior art. Traditionally, the FLOTOX EEPROM cells MC₁₀, MC₁₁, . . . , MC₁₇ and MC₂₀, MC₂₁, . . . , MC₂₇ are arranged in a row having eight columns with each row containing a byte of data. The diagrams of FIGS. 2a and 2b represent the FLOTOX EEPROM cells MC₁₀, MC₁₁, . . . , MC₁₇ and MC₂₀, MC₂₁, . . . , MC₂₇ for containing two bytes. The drains of the select transistors N₀ₐ, N₁ₐ, . . . , N₇ₐ and N_{0d}, N_{1d}, . . . , N_{7d} are respectively connected to an associated bit lines BL0, BL1, . . . , BL7. The bit lines BL0, BL1, . . . , BL7 are associated with a column of the FLOTOX EEPROM cells MC₁₀, MC₁₁, . . . , MC₁₇ and MC₂₀, MC₂₁, . . . , MC₂₇. The sources of the FLOTOX EEPROM transistors N_{0b}, N_{1b}, . . . , N_{7b} and N_{0c}, N_{1c}, . . . , N_{7c} are connected to the common source line SL that is a diffusion implant 110 placed orthogonally to the bit lines BL0, BL1, . . . , BL7 and parallel to the associated rows of the FLOTOX EEPROM cells MC₁₀, MC₁₁, . . . , MC₁₇ and MC₂₀, MC₂₁, . . . , MC₂₇. The common source line SL is connected to a metal line that provides a virtual reference source voltage level (common source line (Vss).

The gates of the select transistors N₀ₐ, N₁ₐ, . . . , N₇ₐ and N_{0d}, N_{1d}, . . . , N_{7d} are formed of the first layer polysilicon 100a and 100b that are aligned to form the word lines WL0 and WL1. The control gates of the FLOTOX EEPROM transistors N_{0b}, N_{1b}, . . . , N_{7b} and N_{0c}, N_{1c}, . . . , N_{7c} are formed of the second layer polysilicon 105a and 105b that are similarly aligned to form the control gate biasing lines CGB0 and CBG1.

The global bit line GBL provides the control gate biasing voltage levels for the control gates of the FLOTOX EEPROM transistors N_{0b}, N_{1b}, . . . , N_{7b} and N_{0c}, N_{1c}, . . . , N_{7c} for programming, erasing, and reading. The control gate biasing voltage levels are transferred from the global bit line GBL to the control gate biasing lines CGB0 and CBG1 through the control gate biasing select transistors N10 and N11. The drains 115a and 115b of the control gate biasing select transistors N10 and N11 are is respectively connected to the global bit line GBL. The sources 120a and 120b of the control gate biasing select transistors N10 and N11 are respectively connected to the control gate biasing lines CGB0 and CBG1. The control gates 125a and 125b are the first layer polysilicon 100a and 110b that forms the word lines WL0 and W11.

The control gate biasing select transistors N10 and N11 are fabricated as either the single layer polysilicon native NMOS transistor with threshold voltage level Vt of +0.3V or a single layer polysilicon enhancement NMOS transistor with a threshold voltage level Vt of around +0.7V. Lower threshold voltage level of the native control gate biasing select transistors N10 and N11 is preferable to the higher threshold voltage level of an enhancement device but at the cost of a bigger layout area in EEPROM byte circuit layout design of the prior art.

The control gate biasing select transistors N10 and N11 are separated by a field oxide isolation layer 130. As described in Smeys and Semenov, the leakage current at high temperatures occurs at the edges of the PN junction of the substrate P-sub and the N+ implants 120a and 120b at the boundary of the field oxide isolation layer 100.

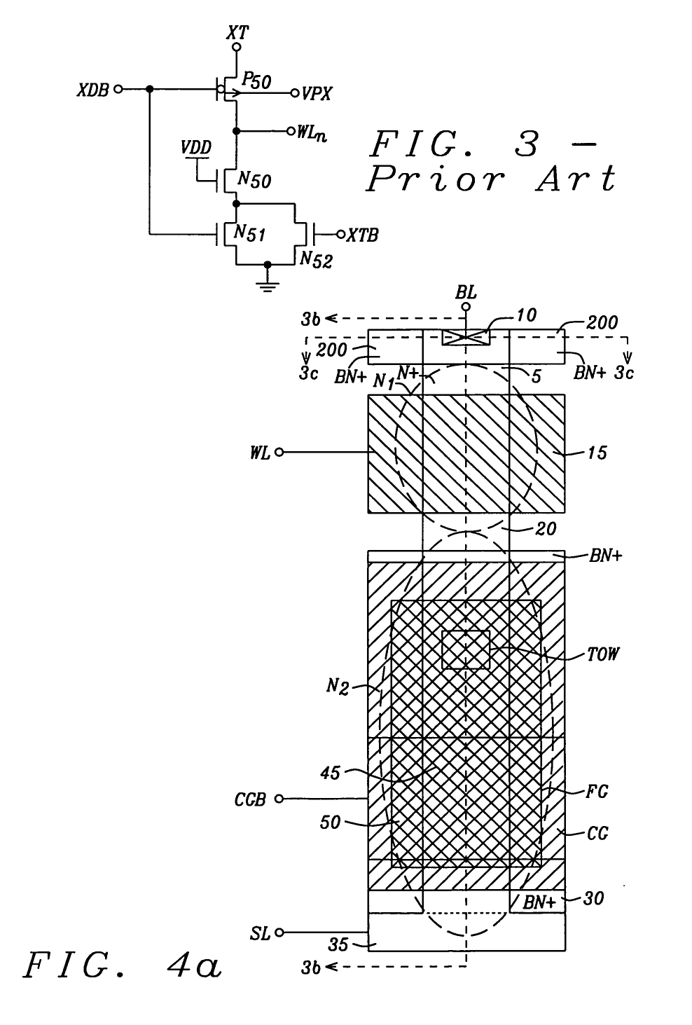

FIG. 3 is a schematic diagram of a word line driver circuit of a row-decoder circuit of the prior art. The row decoder circuit has one word line driver circuit for each word line in the array of FLOTOX EEPROM cells MC₁₀, MC₁₁, . . . , MC₁₇ and MC₂₀, MC₂₁, . . . , MC₂₇ of FIG. 2a. The word line driver circuit has a total of four transistors—one high voltage PMOS transistor, P50, two high voltage NMOS transistors N50 and N51 and one low voltage NMOS transistor N52. The high voltage NMOS transistor N50 blocks the high voltage from the low voltage NMOS transistor N52 thereby effectively increasing the breakdown voltages at node for the word line WL[n]. The required word line voltages during Program and Erase operation are approximately +16V. The structure of the layout of the high voltage NMOS transistor N50 is similar to that of the control gate biasing select transistors N10 and N11 of FIG. 2b. This drain of the high voltage NMOS transistor N50 is defined by a field oxide isolation layer. The high voltage level placed at the node for the word line WL[n] would cause leakage current at the parasitic PN junction between the drain of the high voltage NMOS transistor N50 and the substrate P-sub at the edge of the field oxide at high-temperature operation.

The high voltage NMOS transistors N50 is used to block high voltage applied to the word line WLₙ from being applied to the drains regions of the low voltage NMOS transistor N52 and the high voltage NMOS transistor N51 for area reduction. In addition, the gate of the high voltage NMOS transistor N50 is connected to the power supply voltage source VDD. The breakdown voltages (BVDS) of the drain region of the high voltage NMOS transistor N50 and the high voltage PMOS transistors P50 connected to the word line WLₙ is increased by approximately 1-2V. The permits a higher program and erase high voltage level for faster write time.

The required voltages applied to the word line WLₙ during Program and Erase operations is +16V typically. During the high voltage Program and Erase operations, the voltage level of the signal applied to the node XT and signal applied from the terminal VPX to the N-well bulk of the high voltage PMOS transistor P50 have a magnitude of approximately +16V. Similarly, the voltage level applied to the node XDB swings between approximately +16V and the substrate voltage source VSS during Program and Erase operation. However, the node XDB varies between the power supply voltage source VDD and VSS during Read operation. The voltage applied to the node XTB varies between the power supply voltage source VDD and the substrate voltage source VSS in all operations. With the gate of the high voltage NMOS transistor N50 being connected to the power supply voltage source VDD in all operations, the highest voltage level at the drains of the high voltage NMOS transistor N51 and the low voltage NMOS transistor N52 is kept below the voltage level of the power supply voltage source VDD less the threshold voltage level of the high voltage NMOS transistor N50(VDD−Vt(N50)) in the program, erase and read operations.

In a low voltage read operation, the signals of applied to the nodes XT and VPX have a magnitude equal to the power supply voltage VDD. The drain region of the high voltage NMOS transistor N50 and the high voltage PMOS transistors P50 connected to the word line WLₙ has a parasitic high voltage PN junction areas and PN junction edges in the layout that result in a larger junction leakage current at the edges in higher temperature operations. As a result, this last stage of a high voltage row-decoder circuit of the prior art is prone to failure in higher temperature operation.

The source regions 120a and 120b of the control gate biasing select transistors N10 and N11, the drain regions 5 of the select transistors N₀ₐ, N₁ₐ, . . . , N₇ₐ and N_{0d}, N_{1d}, . . . , N_{7d} and the drain of the high voltage NMOS blocking transistor N50 are fabricated as high voltage N-type regions that aligned with field oxide isolation layers 130 of FIGS. 2c and 55 of FIG. 1d. The N-type drain/source regions 5 form bipolar junctions that are the parasitic N-active/P-substrate devices. These diode junctions have a reverse current leakage before device breakdown that is increased with temperature as defined by the diode law. Normally, the process technology is optimized to keep the leakage current within an acceptable range at the industrial maximum operating temperature of +85° C. But in order to meet the automotive or military temperature specification, the required highest temperature has to be at +125° C. and even +150° C. The diode current is directly related, as is shown in the diode law to the temperature and the reverse saturation current I_{S}. The reverse saturation current I_{S} is directly related to the impurity levels of the drain/source regions 5 and the P-type substrate P-sub.

The impurity concentration at the boundary of the field oxide isolation layers and the P-type substrate P-sub is approximately three fold that of the P-type substrate P-sub. The total leakage at higher temperature is more dominated by the edge boundary at the field oxide isolation layer, rather than other areas of the drain/source regions. The present invention effectively reduces the impurity concentration of PN junction structures at an edge boundary of the field oxide isolation layers to reduce the leakage current. This accomplished by placing a buried implant layer BN+ to separate the drain regions of the select transistors N₀ₐ, N₁ₐ, . . . , N₇ₐ and N_{0d}, N_{1d}, . . . , N_{7d} from the P-type substrate P-sub. The field oxide isolation layer 130 between the source regions 120a and 120b of control gate biasing select transistors N10 and N11 is eliminated and a high voltage NMOS transistor N12 is placed between them. For the high voltage NMOS blocking transistor N50 in the word line driver, two transistors are formed in series with the high voltage NMOS blocking transistor N50 to reduce the impurity concentration of PN junction structures at the boundary of the field oxide isolation layers to reduce the leakage current.

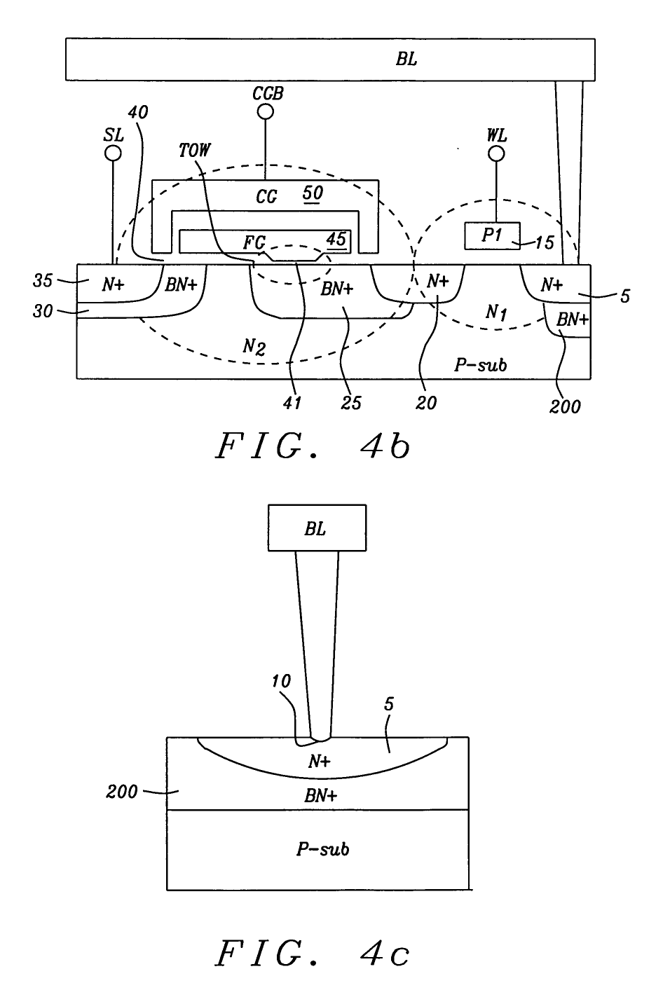

FIGS. 4a and 4b are respectively a top view and a cross sectional view that illustrate the physical layout for the two-transistor FLOTOX EEPROM cell as formed in a substrate P-sub embodying the principles of the present invention. FIG. 4c is a cross sectional view of the drain region 5 of the select transistor N₁ of the FLOTOX EEPROM cell embodying the principles of the present invention. The structure of the FLOTOX EEPROM cell as shown is essentially identical to that of FIGS. 1a-1d except the buried implant diffusion layer 200 is implanted such that it is placed beneath the drain 5 of the select transistor N₁ and the field oxide isolation layers 55 are eliminated such that in an array of the FLOTOX EEPROM cells MC₁₀, MC₁₁, . . . , MC₁₇ and MC₂₀, MC₂₁, . . . , MC₂₇ embodying the principles of the present invention, the buried implant diffusion layers 200 of adjacent FLOTOX EEPROM cells MC₁₀, MC₁₁, . . . , MC₁₇ and MC₂₀, MC₂₁, . . . , MC₂₇ are connected. In fact in practice, a single masking feature will define the buried implant diffusion layers 200. The buried implant diffusion layer 200 prevents the excess leakage current from increasing significantly when the drain region 5 is connected to a high voltage and the operating temperature is elevated. As is known in the art, the reverse saturation current is inversely proportional to the carrier donor and acceptor concentrations at the n side and p side of a PN junction. The concentration of the N+ material of the drain 5 of the select transistor N₁ 1×10¹⁵ electrons/cm³ and the concentration of the for the buried implant diffusion layer BN+ 200 is 1×10¹⁴ electrons/cm³. The lower concentration at the PN junction of the buried implant diffusion layer 200 means that the reverse leakage current at an elevated temperature is decreased.

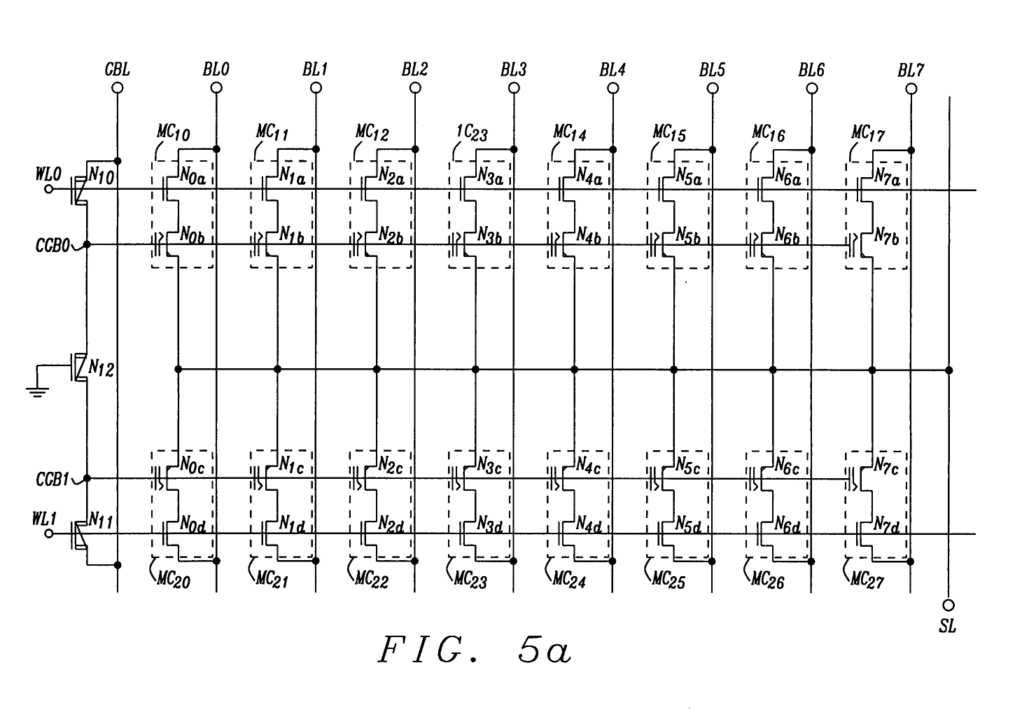

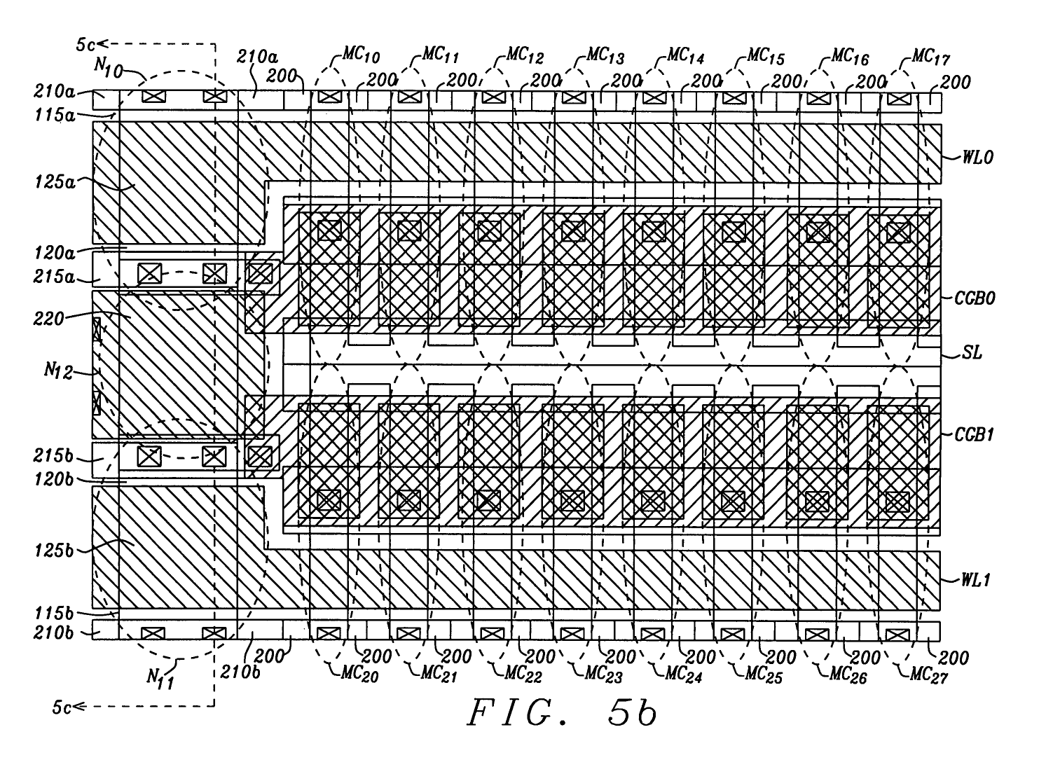

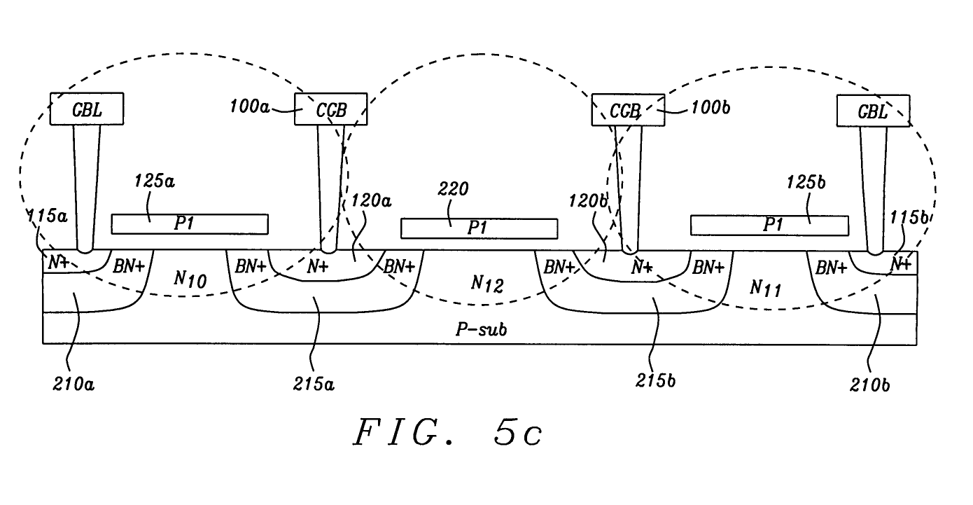

FIG. 5a is a schematic diagram of a two-byte section of an array of FLOTOX EEPROM cells embodying the principles of the present invention. FIG. 5b is a diagram of a top view of a two-byte section of the array of FLOTOX EEPROM cells embodying the principles of the present invention with the control gate biasing select transistors N10 and N11 with the anti-leakage transistor N12. FIG. 5c is a diagram illustrating a cross section of the two-byte section of the array of FLOTOX EEPROM cells embodying the principles of the present invention showing the control gate biasing select transistors N10 and N11 with the anti-leakage transistor N12. The anti-leakage transistor N12 is placed between the control gate biasing select transistors N10 and N11 thus eliminating the need for a field oxide isolation layer between the control gate biasing select transistors N10 and N11.

The array of the FLOTOX EEPROM cells MC₁₀, MC₁₁, . . . , MC₁₇ and MC₂₀, MC₂₁, . . . , MC₂₇ embodying the principles of the present invention are structured and operate essentially identically to those as shown in FIGS. 2a, 2b, and 2c with the following exceptions. The drains 5 of the select transistor N₁, as shown in FIGS. 4a and 4b, are contained in a buried implant diffusion layer 200. The buried implant diffusion layers 200 of the adjacent FLOTOX EEPROM cells MC₁₀, MC₁₁, . . . , MC₁₇ and MC₂₀, MC₂₁, . . . , MC₂₇ create a buried layer at the boundary of the array of the FLOTOX EEPROM cells MC₁₀, MC₁₁, . . . , MC₁₇ and MC₂₀, MC₂₁, . . . , MC₂₇. The drain regions 115a and 115b of the control gate biasing select transistors N10 and N11 have a buried layer BN+ 210a and 210b placed beneath that is essentially connected with the buried implant diffusion layer 200 of the FLOTOX EEPROM cells MC₁₀, MC₁₁, . . . , MC₁₇ and MC₂₀, MC₂₁, . . . , MC₂₇. The source regions 120a and 120b have the buried layer BN+ 215a and 215b placed beneath them. A control gate 220 is formed of the first layer polysilicon. The control gate 220 of the anti-leakage transistor N12 is connected to a ground reference voltage source to prevent current leakage flow between control gate biasing select transistors N10 and N11 to effect a full electric isolation between the control gate biasing select transistors N10 and N11.

The buried implant diffusion layers 200, 210a, 210b, 215a, and 215b prevent the excess leakage current from increasing significantly when the drain regions 5 and 210a and 210b and the source regions 215a and 215b are connected to a high voltage and the operating temperature is elevated. As described above, the reverse saturation current is inversely proportional to the carrier donor and acceptor concentrations at the n side and p side of a PN junction. The concentration of the N+ material of the drain 5 of the select transistor N₁ is 1×10¹⁵ electrons/cm³ and the concentration of the for the buried implant diffusion layers BN+ 200, 210a, 210b, 215a, and 215b is 1×10¹⁴ electrons/cm³. The lower concentration at the PN junction of the buried implant diffusion layer 200 means that the reverse leakage current at an elevated temperature is decreased.

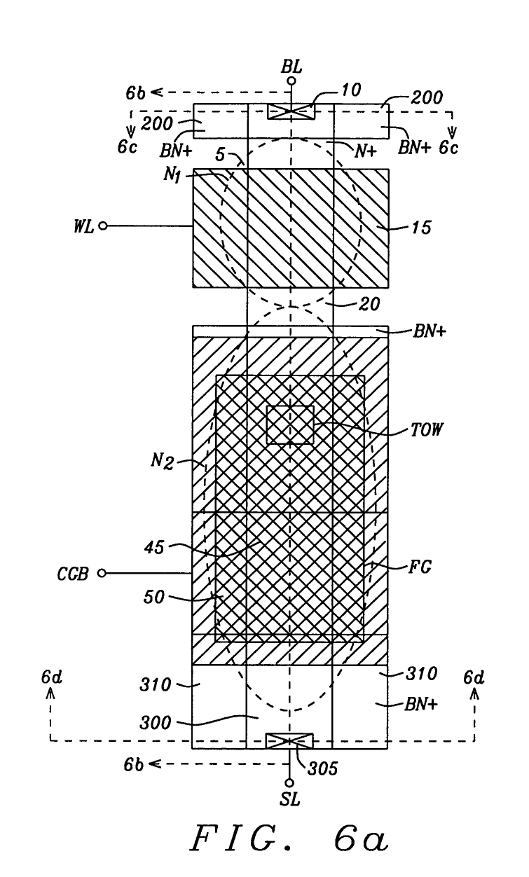

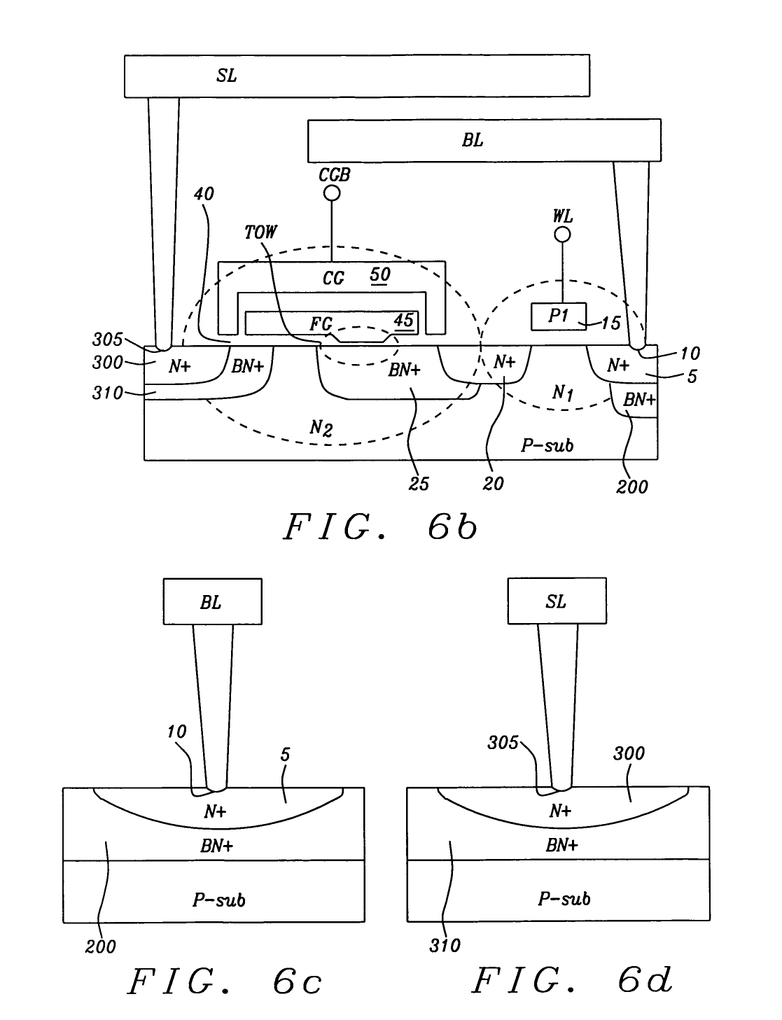

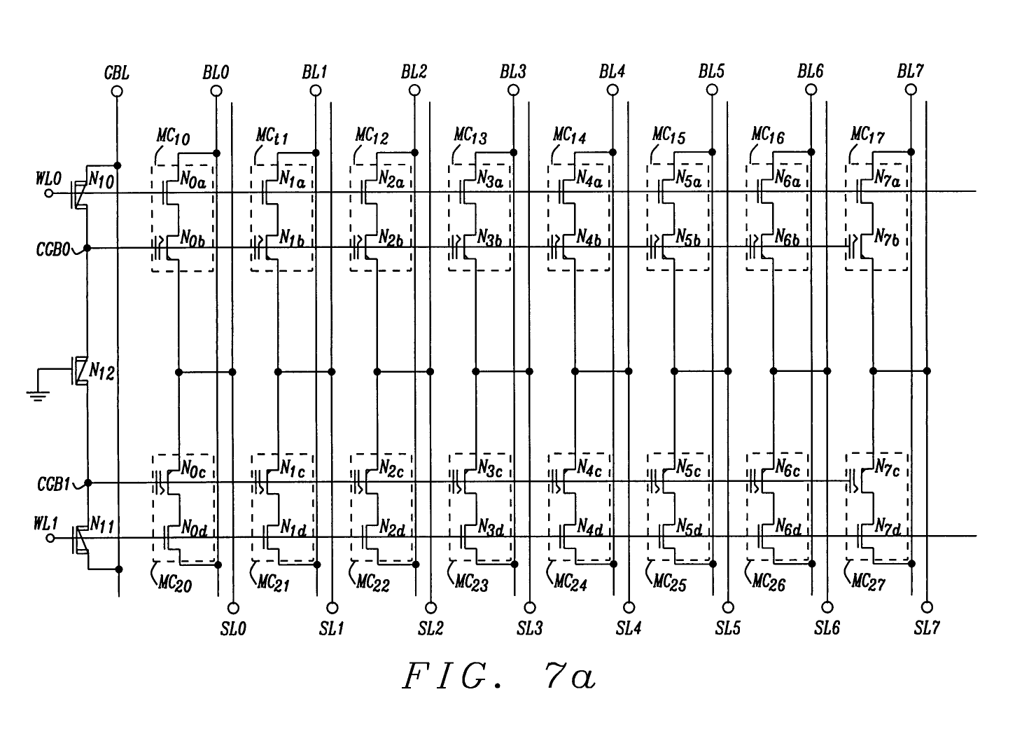

FIGS. 6a and 6b are respectively a top view and a cross sectional view that illustrate the physical layout for some embodiments of a two-transistor FLOTOX EEPROM cell as formed in a substrate P-sub embodying the principles of the present invention. FIG. 6c is a cross sectional view of the drain of the select transistor N₁ for the embodiments of the FLOTOX EEPROM cell of FIGS. 6a and 6b embodying the principles of the present invention. FIG. 6d is a cross sectional view of the source of the FLOTOX EEPROM transistor N₂ for the embodiments of the FLOTOX EEPROM cell of FIGS. 6a and 6b embodying the principles of the present invention.

The structure of the FLOTOX EEPROM cell as shown is essentially identical to that of FIGS. 1a and 4a-4c, except the source region 300 of the FLOTOX EEPROM transistor N₂ is a single N-type diffusion rather than a portion of the N-type diffusion 35 of FIGS. 4a and 4b that form the source line SL. The source region 300 has a contact metallurgy 305 that is connected to the metal source line SL. In the present embodiments, the metal source line SL is associated with a single column of the FLOTOX EEPROM cells MC₁₀, MC₁₁, . . . , MC₁₇ and MC₂₀, MC₂₁, . . . , MC₂₇ and is parallel with the metal bit line BL connected to the FLOTOX EEPROM cells MC₁₀, MC₁₁, . . . , MC₁₇ and MC₂₀, MC₂₁, . . . , MC₂₇ associated with the metal source line SL.

A buried implant diffusion layer 310 is implanted such that it is placed to contain the source region 300 of the FLOTOX EEPROM transistor N₂ in a fashion similar to the buried implant diffusion layer 200 that is implanted beneath the drain 5 of the select transistor N₁. As with the buried implant diffusion layer 200, the field oxide isolation layers 55 are eliminated such that in an array of the FLOTOX EEPROM cells MC₁₀, MC₁₁, . . . , MC₁₇ and MC₂₀, MC₂₁, . . . , MC₂₇ embodying the principles of the present invention, the buried implant diffusion layers 310 of adjacent FLOTOX EEPROM cells MC₁₀, MC₁₁, . . . , MC₁₇ and MC₂₀, MC₂₁, . . . , MC₂₇ are connected. In fact in practice, a single masking feature will define the buried implant diffusion layers 310. The buried implant diffusion layer 310 prevents the excess leakage current from increasing significantly when the source region 300 is connected to a high voltage and the operating temperature is elevated. As described above, the reverse saturation current is inversely proportional to the carrier donor and acceptor concentrations at the n side and p side of a PN junction. The concentration of the N+ material of the drain 5 of the select transistor N₁ 1×10¹⁵ electrons/cm³ and the concentration of the for the buried implant diffusion layer BN+ 200 is 1×10¹⁴ electrons/cm³. The lower concentration at the PN junction of the buried implant diffusion layer 310 means that the reverse leakage current at an elevated temperature is decreased.

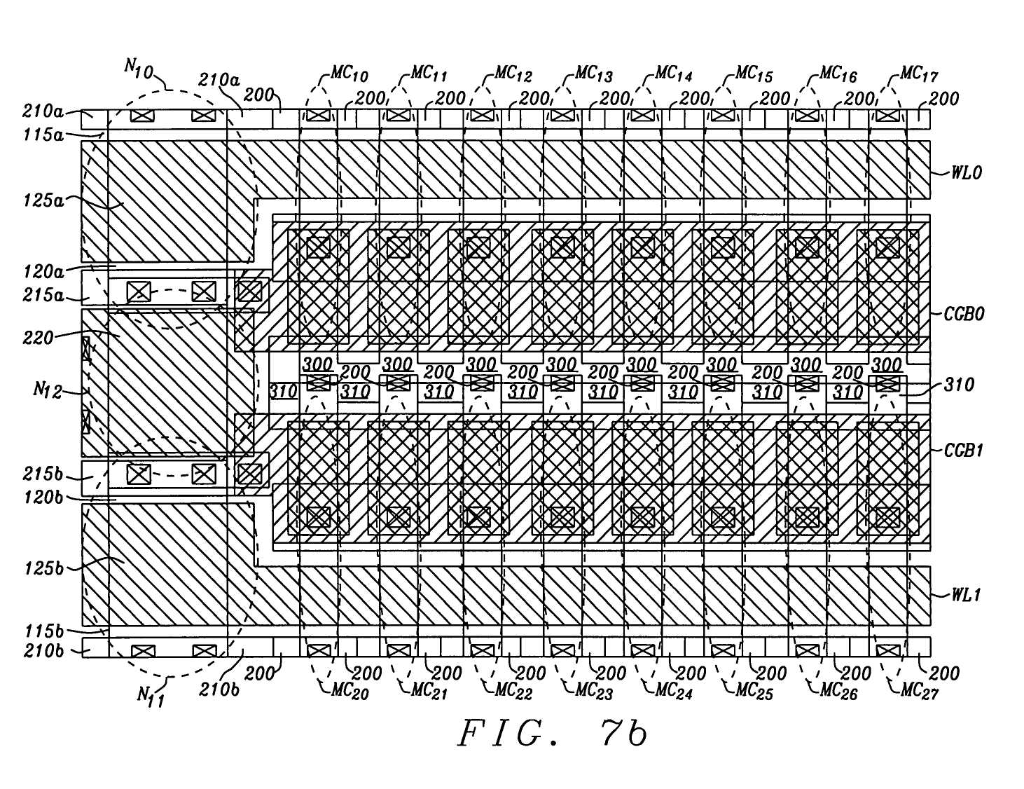

FIG. 7a is a schematic diagram of a two-byte section of an array of FLOTOX EEPROM cells MC₁₀, MC₁₁, . . . , MC₁₇ and MC₂₀, MC₂₁, . . . , MC₂₇ embodying the principles of the present invention. FIG. 7b is a diagram of a top view of a two-byte section of the array of FLOTOX EEPROM cells MC₁₀, MC₁₁, . . . , MC₁₇ and MC₂₀, MC₂₁, . . . , MC₂₇ embodying the principles of the present invention with the control gate biasing select transistors N10 and N11 with the anti-leakage transistor N12. The anti-leakage transistor N12 is placed between the control gate biasing select transistors N10 and N11 thus eliminating the need for a field oxide isolation layer between the control gate biasing select transistors N10 and N11.

The array of the FLOTOX EEPROM cells MC₁₀, MC₁₁, . . . , MC₁₇ and MC₂₀, MC₂₁, . . . , MC₂₇ embodying the principles of the present invention are structured and operate essentially identically to those as shown in FIGS. 5a and 5b with the following exceptions. The source of the 300 of the FLOTOX EEPROM transistor N₂ is a single N-type diffusion as described in FIGS. 6b and 6d. The source 300 diffusion of each of the FLOTOX EEPROM transistor N₂ of each of the FLOTOX EEPROM cells MC₁₀, MC₁₁, . . . , MC₁₇ and MC₂₀, MC₂₁, . . . , MC₂₇ has a contact metallurgy 305 that is connected to one the metal source lines SL0, SL1, . . . , SL7. In the present embodiments, the metal source lines SL0, SL1, . . . , SL7 are each associated with a single column of the FLOTOX EEPROM cells MC₁₀, MC₁₁, . . . , MC₁₇ and MC₂₀, MC₂₁, . . . , MC₂₇ and is parallel with the metal bit line BL0, BL1, BL7 connected to the FLOTOX EEPROM cells MC₁₀, MC₁₁, . . . , MC₁₇ and MC₂₀, MC₂₁, . . . , MC₂₇ associated with the metal source lines SL0, SL1, . . . , SL7.

The source of the 300 of the FLOTOX EEPROM transistor N₂, as shown in FIGS. 6b and 6d, have a buried implant diffusion layer 310 is placed beneath them. The buried implant diffusion layers 310 of the adjacent FLOTOX EEPROM cells MC₁₀, MC₁₁, . . . , MC₁₇ and MC₂₀, MC₂₁, . . . , MC₂₇ create a buried layer at the boundary of the array of the FLOTOX EEPROM cells MC₁₀, MC₁₁, . . . , MC₁₇ and MC₂₀, MC₂₁, . . . , MC₂₇.

The buried implant diffusion layers 200, 210a, 210b, 215a, and 215b the are as described in FIGS. 5b and 5c. The buried implant diffusion layers 200, 210a, 210b, 215a, and 215b with the a buried implant diffusion layers 310 prevent the excess leakage current from increasing significantly when the drain regions 5 and 210a and 210b and the source regions 215a and 215b and 300 are connected to a high voltage and the operating temperature is elevated. As described above, the reverse saturation current is inversely proportional to the carrier donor and acceptor concentrations at the N side and P side of a PN junction. The concentration of the N+ material of the drain 5 of the select transistor N₁ and the source 300 of the FLOTOX EEPROM transistor N₂ is 1×10¹⁵ electrons/cm³ and the concentration of the for the buried implant diffusion layers BN+ 200, 210a, 210b, 215a, 215b, and 310 is 1×10¹⁴ electrons/cm³. The lower concentration at the PN junction of the buried implant diffusion layer 200 means that the reverse leakage current at an elevated temperature is decreased.

FIG. 8 is a schematic diagram of a word line driver circuit of a row-decoder circuit embodying the principles of the present invention. The row decoder circuit has one word line driver circuit for each word line WLn in the array of FLOTOX EEPROM cells MC₁₀, MC₁₁, . . . , MC₁₇ and MC₂₀, MC₂₁, . . . , MC₂₇ of FIGS. 5a and 7a. The word line driver circuit has a the four transistors—one high voltage PMOS transistor, P50, two high voltage NMOS transistors N50 and N51 and one low voltage NMOS transistor N52. The high voltage NMOS transistor N50 blocks the high voltage from the low voltage NMOS transistor N52 thereby effectively increasing the breakdown voltages at node for the word line WL[n] as shown in FIG. 3. The required word line voltages during Program and Erase operation are approximately +16V. As described in FIG. 3, the structure of the layout of the high voltage NMOS transistor N50 is similar to that of the control gate biasing select transistors N10 and N11 of FIG. 2b. A high voltage NMOS transistor N53a and a low voltage NMOS transistor N53b are connected to the high voltage NMOS transistor N50 so that the PN junction edges and PN junctions areas of the parasitic bipolar PN-junction connected to the critical word line WL[N] are dramatically reduced, thus decreasing the current leakage during the higher temperature operation.

The basic structure and operation of the word line driver circuit of a row-decoder circuit of FIG. 8 are essentially identical to that of FIG. 3. The source of the high voltage NMOS transistor N53a is connected to the word line WL[n]. The drain of the high voltage NMOS transistor N53a is floating. The drain of the low voltage NMOS transistor N53b is connected to the source of the high voltage NMOS transistor N50 and the drains of the high voltage NMOS transistor N51 and the low voltage NMOS transistor N52. The source of the low voltage NMOS transistor N53b is left floating. The drain of the high voltage NMOS transistor N53a and the source of the low voltage NMOS transistor N53b are floating as a result of a special layout technique that reduces the PN junction edges and PN junctions areas of the parasitic bipolar PN-junction connected to the critical word line WL[N].

The addition of the high voltage NMOS transistor N51 and the low voltage NMOS transistor N52 allows the layout area to remain almost the same with less penalty in die size while achieving performance enhancement in higher temperature operation. The PN junction area and PN junction edges of the drain/source region of the high voltage NMOS transistors N50 and N51 connected to the word line WLₙ is greatly reduced such that the circuit is able to operate at higher temperature environment.

The addition of the high voltage NMOS transistor N53a and the low voltage NMOS transistor N53b takes advantage of the available layout room in the row decoder to reduce the parasitic bipolar PN junction area and PN junction edges can be achieved for higher temperature operation of the present invention. Since, the drain region of the high voltage NMOS transistor N50 and the high voltage PMOS transistors P50 connected to the word line WLₙ have the only high voltage PN junction area and PN junction edges within the row decoder circuit, decreasing of the carrier concentrations at the parasitic bipolar PN junction area and PN junction edges is accomplished with the addition of the high voltage NMOS transistor N53a and the low voltage NMOS transistor N53b.

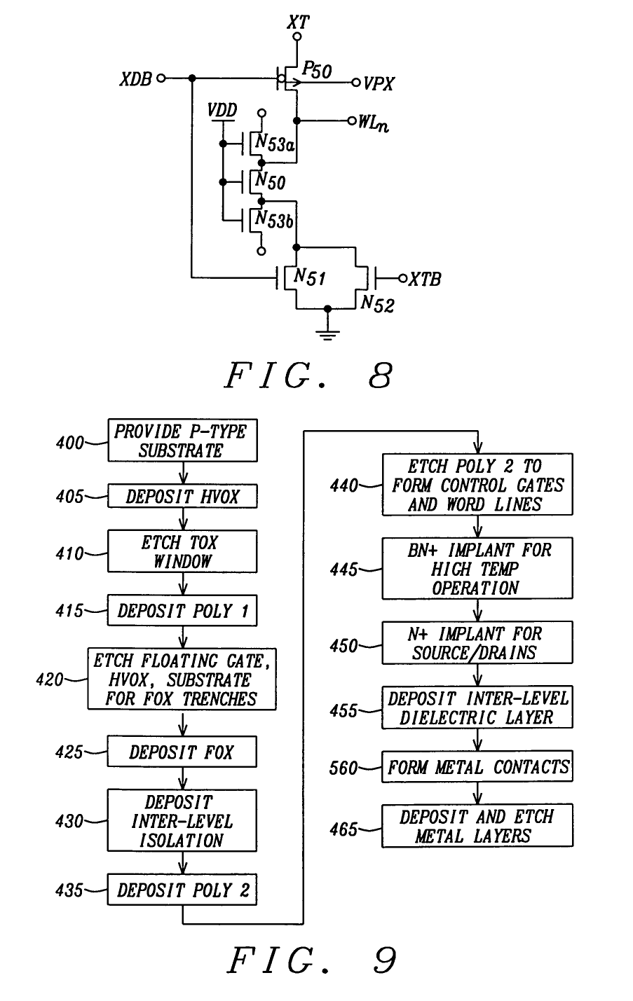

FIG. 9 is a flow diagram for a method of fabricating embodiments of an array of two-transistor FLOTOX EEPROM cells formed in a substrate embodying the principles of the present invention. The method begins with providing (Box 400) a substrate. A high voltage oxide is deposited (Box 405) on the substrate. The high voltage oxide is etched (Box 410) to form a tunnel oxide window for each of the FLOTOX EEPROM transistors. A first level of polysilicon is deposited (Box 415) on the surface of the substrate over the high voltage oxide and the tunnel oxide windows. The first level poly crystalline silicon, the high voltage oxide, and the substrate is etched (Box 420) to form the shallow trenches to receive the field oxide to define the floating gates of the FLOTOX EEPROM cells and the gates of the select gating transistors and the transistors of the supporting logic. The field oxide is formed (Box 425) on the surface of the substrate and fills the trenches. An inter-level isolation is formed (Box 430) and a second level polysilicon is deposited (Box 435) on the surface of the substrate. The second level polysilicon is then etched (Box 440) to form the control gates of the FLOTOX EEPROM transistors and the word lines of the array of the FLOTOX EEPROM cells. Other appropriate interconnections will also be formed at this time in the second level polysilicon.

Buried implant layers are diffused (Box 445) into the substrate for high temperature operation of the high voltage transistors such as the FLOTOX EEPROM transistors and the select gate transistor of the FLOTOX EEPROM cells. The concentration of the for the buried implant diffusion layers is 1×10¹⁴ electrons/cm³. This lower concentration at the PN junction of the buried implant diffusion layers means that a reverse leakage current at an elevated temperature is decreased when compared to the normal concentration of the source/drain regions of the high voltage FLOTOX EEPROM transistors and the select gate transistor of the FLOTOX EEPROM cells and other high voltage transistors in the supporting driver circuits of the array of FLOTOX EEPROM cells. This concentration of the N+ material of the drain/source regions of the select transistor and the source of the FLOTOX EEPROM transistor is 1×10¹⁵ electrons/cm³. This elevated concentration would cause a larger reverse leakage current at an elevated temperature if not for the buried layer embodying the principles of this invention. In the case of a P-type substrate, the donor species are Boron, arsenic, or preferably phosphorus.

In the FLOTOX EEPROM cells of FIGS. 4a-c and 6a-d, the buried layers 200 and 310 do not decrease the parasitic PN junction areas and PN junction edges of drain region of the select transistor, N₁ and the source region of the FLOTOX EEPROM transistor N₂ beneath the contacts of 10 and 305 of FIGS. 6a, 6b, and 6d. The added BN+ phosphorus implant of the buried layers 200 and 310 offset the lighter Boron implant dose on the overlapping areas of P-substrate P-sub and heavier Boron implant of the field-isolation layer 55. The BN+ implant dose of the buried layers 200 and 310 is the opposite type of implant to Boron such that the buried layers 200 and 310 penetrate deeper into substrate P-sub to reduce the Boron's concentration. As a result, the parasitic leakage current would be reduced at both PN junction areas and PN junction edges for the higher temperature operating conditions due to the lower concentration of the dopants at the parasitic PN junctions.

The N-type sources and drains are implanted (Box 450) with a donor impurity to form the sources and drains of the FLOTOX EEPROM transistors and the select gate transistor of the FLOTOX EEPROM cells as well as the NMOS and PMOS transistors of the supporting circuits. An inter-level dielectric layer is deposited (Box 455) on the surface of the substrate and etched to make opening for metal contacts to the drain/source regions. The metal contacts are formed (Box 460). Metal layers are deposited and etched (Box 465) with inter-level dielectric layers between each metal layer. The etched metal layers form the interconnections such as the bit lines BL0, BL1, . . . , BL7 of FIGS. 5a and 7a and the source lines SL0, SL1, . . . , SL7 of FIG. 7a.

The substrate as described above is a p-type substrate with n-type drains, sources, and buried implant layers may also be n-type substrate with p-type drains, sources, and buried implant layers and still be in keeping with the principles of this invention. The invention as shown with a FLOTOX EEPROM array, other nonvolatile memory arrays or even other high voltage applications may employ the buried implant layers for minimizing leakage current resulting from operating a nonvolatile memory at elevated temperatures and be in keeping with embodying the principles of this invention. While this invention has been particularly shown and described with reference to the preferred embodiments thereof, it will be understood by those skilled in the art that various changes in form and details may be made without departing from the spirit and scope of the invention.

The invention claimed is:

1. A method for fabricating a high temperature integrated circuit comprising:
forming a drain/source diffusion of a first conductivity type within a surface of a substrate and separated from the substrate and an edge of a field isolation layer such that a concentration of an impurity species at the edge of the field isolation layer decreases a leakage occurring with high voltage and high temperature applied to the source/drain diffusion.

2. The method for fabricating the high temperature integrated circuit of claim 1 further comprises forming a buried implant layer between the drain/source diffusion and the field isolation layer and the substrate to separate the drain/source diffusion from the substrate and the field isolation layer.

3. The method for fabricating the high temperature integrated circuit of claim 2 wherein a concentration of an implanted impurity species material of the source of the charge retaining transistor is 1×10¹⁵ charges/cm³ and the concentration of the buried implant region is 1×10¹⁴ charges/cm³ such that the lower concentration at the parasitic PN junction of the buried implant diffusion layer decreases the reverse leakage current at an elevated temperature.

4. A nonvolatile memory array driver circuit comprises:
a plurality of driver transistors, each driver transistor comprises:
a drain connected to a high voltage distribution conductor,
a source connected to the nonvolatile memory array, and
a gate connected to a select circuit for choosing at least one of the multiple driver transistors for activation,
a plurality of anti-leakage transistors connected between adjacent driver transistors such that each of the anti-leakage transistors includes:
a drain connected to the source of one driver transistor of the multiple driver transistors,
a source connected to an adjacent driver transistor, and
a gate connected to a biasing voltage source to bias the anti-leakage transistor to prevent excess junction leakage current at elevated temperatures at the edges of the parasitic PN-junctions of the driver transistors.

5. A nonvolatile memory array driver circuit comprising;
a high voltage blocking transistor comprising:
a drain connected to a driver transistor and to a terminal connected to the memory array;
a source connected to a low voltage switching circuit for connecting an output terminal of the nonvolatile memory array driver circuit to a reference voltage level; and
a gate connected to a power supply voltage source to bias the low voltage switching circuit to a voltage level no greater than the voltage level of the power supply voltage source less a threshold voltage level of the high voltage blocking transistor when a high voltage level is applied to the output terminal;
two anti-leakage transistors connected such that a source of the first anti-leakage transistor is connected to a drain of the high voltage blocking transistor and a drain of the second anti-leakage transistor is connected to a source of the high voltage blocking transistor, wherein a drain of the first anti-leakage transistor and a source of the second anti-leakage transistor are floating and gates of the first and second anti-leakage transistors are connected to the power supply voltage source such that the two anti-leakage transistors prevent excess junction leakage current at elevated temperatures at the edges of the parasitic PN-junctions of the driver transistors.

6. The nonvolatile memory array driver circuit of claim 6 wherein the nonvolatile memory array driver circuit is a charge-pump, column-decoder, row-decoder, page-buffer or the memory cell array that requires a high voltage for programming or erasing the nonvolatile memory circuit.

7. A nonvolatile memory cell comprising:
a select transistor having a drain region of a first conductivity type implanted in a substrate with a contact metallurgy connected to communicate with a bit line;
a first buried implant region diffused into the substrate and containing the drain region for preventing junction leakage current at elevated temperatures at the edges of a parasitic PN-junction of the drain region in proximity to field isolation regions bordering the nonvolatile memory cell.

8. The nonvolatile memory cell of claim 7 further comprising:
a charge retaining transistor having a source region of the first conductivity type implanted in a substrate with a contact metallurgy connected to communicate with a source line that is in parallel with the bit line.
a second buried implant region diffused into the substrate and containing the source region for preventing excess junction leakage current at elevated temperatures at the edges of a parasitic PN-junction of the source region in proximity to field isolation regions bordering the nonvolatile memory cell.

9. The nonvolatile memory cell of claim 7 wherein a concentration of an implanted impurity species material of the drain of the select transistor is 1×10¹⁵ charges/cm³ and the concentration of the first buried implant region is 1×10¹⁴ charges/cm³ such that the lower concentration at the parasitic PN junction of the buried implant diffusion layer decreases the reverse leakage current at an elevated temperature.

10. The nonvolatile memory cell of claim 8 wherein a concentration of an implanted impurity species material of the source of the charge retaining transistor is 1×10¹⁵ charges/cm³ and the concentration of the second buried implant region is 1×10¹⁴ charges/cm³ such that the lower concentration at the parasitic PN junction of the second buried implant diffusion layer decreases the reverse leakage current at an elevated temperature.

11. A method for fabricating a nonvolatile memory cell comprising:
implanting a drain region of a select transistor of a first conductivity type within a substrate;
connecting the drain region to communicate with a bit line;
diffusing a first buried implant region into the substrate beneath the location of the drain region to contain the drain region to prevent excess junction leakage current at elevated temperatures at the edges of a parasitic PN-junction of the drain region in proximity to field isolation regions bordering the nonvolatile memory cell.

12. The method for fabricating the nonvolatile memory cell of claim 10 comprising:
implanting a source region of a charge retaining transistor of the first conductivity type within a substrate;
connecting the source region to communicate with a source line;
diffusing a second buried implant region into the substrate beneath the location of the source region to contain the drain region to prevent excess junction leakage current at elevated temperatures at the edges of a parasitic PN-junction of the source region in proximity to field isolation regions bordering the nonvolatile memory cell.

13. The method for fabricating the nonvolatile memory cell of claim 11 wherein a concentration of an implanted impurity species material of the drain of the select transistor is 1×10¹⁵ charges/cm³ and the concentration of the first buried implant region is 1×10¹⁴ charges/cm³ such that the lower concentration at the parasitic PN junction of the buried implant diffusion layer decreases the reverse leakage current at an elevated temperature.

14. The method for fabricating the nonvolatile memory cell of claim 12 wherein a concentration of an implanted impurity species material of the source of the charge retaining transistor is 1×10¹⁵ charges/cm³ and the concentration of the second buried implant region is 1×10¹⁴ charges/cm³ such that the lower concentration at the parasitic PN junction of the second buried implant diffusion layer decreases the reverse leakage current at an elevated temperature.

15. An integrated circuit formed in a substrate comprising:
an array of nonvolatile memory cells each nonvolatile memory cell comprising:
a charge retaining transistor having a source connected to a source line, drain and a gate, and
a select transistor having a source connected to the drain of the charge retaining transistor, a drain connected to a bit line, and a gate;
wherein a first buried implant region is diffused into the substrate and containing the drain region of the select transistor for preventing junction leakage current at elevated temperatures at the edges of a parasitic PN-junction of the drain region in proximity to field isolation regions bordering of each of the nonvolatile memory cell;
a plurality of control gate biasing driver circuits, each control gate biasing driver circuits comprising:
a plurality of driver transistors, each driver transistor comprises:
a drain connected to a high voltage distribution conductor,
a source connected to the nonvolatile memory array, and
a gate connected to a select circuit for choosing at least one of the multiple driver transistors for activation,
a plurality of anti-leakage transistors connected between driver transistors of adjacent control gate biasing circuits such that each of the anti-leakage transistors includes:
a drain connected to the source of one driver transistor of the multiple driver transistors,
a source connected to an adjacent driver transistor, and
a gate of the anti-leakage transistors is connected to a biasing voltage source to bias the anti-leakage transistor to prevent excess junction leakage current at elevated temperatures at the edges of the parasitic PN-junctions of the driver transistors;

16. The integrated circuit of claim 15 further comprising:
nonvolatile memory array driver circuit for communicating from control circuitry of the integrated circuit and the array of nonvolatile memory cells comprising;
a high voltage blocking transistor comprising:
a drain connected to a driver transistor, and to a terminal connected to the memory array;
a source connected to a low voltage switching circuit for connecting an output terminal of the nonvolatile memory array driver circuit to a reference voltage level; and
a gate connected to a power supply voltage source to bias the low voltage switching circuit to a voltage level no greater than the voltage level of the power supply voltage source less a threshold voltage level of the high voltage blocking transistor when a high voltage level is applied to the output terminal;
two anti-leakage transistors connected such that a source of the first anti-leakage transistor is connected to a drain of the high voltage blocking transistor and a drain of the second anti-leakage transistor is connected to a source of the high voltage blocking transistor, wherein a drain of the first anti-leakage transistor and a source of the second anti-leakage transistor are floating and gates of the first and second anti-leakage transistors are connected to the power supply voltage source such that the two anti-leakage transistors prevent excess junction leakage current at elevated temperatures at the edges of the parasitic PN-junctions of the driver transistors.

17. The integrated circuit of claim 15 wherein a concentration of an implanted impurity species material of the drain of the select transistor is 1×10¹⁵ charges/cm³ and the concentration of the first buried implant region is 1×10¹⁴ charges/cm³ such that the lower concentration at the parasitic PN junction of the buried implant diffusion layer decreases the reverse leakage current at an elevated temperature.

18. The integrated circuit of claim 16 wherein a concentration of an implanted impurity species material of the source of the charge retaining transistor is 1×10¹⁵ charges/cm³ and the concentration of the second buried implant region is 1×10¹⁴ charges/cm³ such that the lower concentration at the parasitic PN junction of the second buried implant diffusion layer decreases the reverse leakage current at an elevated temperature.

19. The integrated circuit of claim 16 wherein the nonvolatile memory array driver circuit is a charge-pump, column-decoder, row-decoder, page-buffer or the memory cell array that requires a high voltage for programming or erasing the nonvolatile memory circuit.

20. A method for fabricating a nonvolatile memory device on a substrate comprising:
forming an array of nonvolatile memory cells comprising:
implanting a drain regions of select transistors of the nonvolatile memory cells within the substrate;
connecting the drain region to communicate with a bit line;
diffusing a first buried implant region into the substrate beneath the location of the drain region to contain the drain region to prevent excess junction leakage current at elevated temperatures at the edges of a parasitic PN-junction of the drain region in proximity to field isolation regions bordering the nonvolatile memory cell;
forming a plurality of control gate biasing driver circuits, each control gate biasing driver circuits comprising:
forming a plurality of driver transistors comprising:
forming a drain connected to a high voltage distribution conductor,
forming a source connected to the nonvolatile memory array, and
forming a gate connected to a select circuit for choosing at least one of the multiple driver transistors for activation,
forming a plurality of anti-leakage transistors between driver transistors of adjacent control gate biasing circuits comprising:
forming a drain,
connecting the drain to the source of one driver transistor of the multiple driver transistors,
forming a source,
connecting the source to a second adjacent driver transistor, and
forming a gate,
connecting the gate to a biasing voltage source to bias the anti-leakage transistor to prevent excess junction leakage current at elevated temperatures at the edges of the parasitic PN-junctions of the driver transistors.

21. The method for fabricating the nonvolatile memory device of claim 20 wherein forming the nonvolatile memory cell further comprises:
implanting a source region of a charge retaining transistor of the first conductivity type within a substrate;
connecting the source region to communicate with a source line;
diffusing a second buried implant region into the substrate beneath the location of the source region to contain the drain region to prevent excess junction leakage current at elevated temperatures at the edges of a parasitic PN-junction of the source region in proximity to field isolation regions bordering the nonvolatile memory cell.

22. The method for fabricating the nonvolatile memory device of claim 20 further comprising:
forming a nonvolatile memory array driver circuit comprising;
forming a high voltage blocking transistor comprising:
forming a drain connected to a driver transistor, and to a terminal connected to the memory array;
forming a source connected to a low voltage switching circuit for connecting an output terminal of the nonvolatile memory array driver circuit to a reference voltage level; and
forming a gate connected to a power supply voltage source to bias the low voltage switching circuit to a voltage level no greater than the voltage level of the power supply voltage source less a threshold voltage level of the high voltage blocking transistor when a high voltage level is applied to the output terminal;
forming two anti-leakage transistors connected such that a source of the first anti-leakage transistor is connected to a drain of the high voltage blocking transistor and a drain of the second anti-leakage transistor is connected to a source of the high voltage blocking transistor, wherein a drain of the first anti-leakage transistor and a source of the second anti-leakage transistor are floating and gates of the first and second anti-leakage transistors are connected to the power supply voltage source such that the two anti-leakage transistors prevent excess junction leakage current at elevated temperatures at the edges of the parasitic PN junctions of the driver transistors.

23. The method for fabricating the nonvolatile memory device of claim 20 wherein a concentration of an implanted impurity species material of the drain of the select transistor is 1×10¹⁵ charges/cm³ and the concentration of the first buried implant region is 1×10¹⁴ charges/cm³ such that the lower concentration at the parasitic PN junction of the buried implant diffusion layer decreases the reverse leakage current at an elevated temperature.

24. The method for fabricating the nonvolatile memory device of claim 21 wherein a concentration of an implanted impurity species material of the source of the charge retaining transistor is 1×10¹⁵ charges/cm³ and the concentration of the second buried implant region is 1×10¹⁴ charges/cm³ such that the lower concentration at the parasitic PN junction of the second buried implant diffusion layer decreases the reverse leakage current at an elevated temperature.

25. The method for fabricating the nonvolatile memory device of claim 21 wherein the nonvolatile memory array driver circuit is a charge-pump, column-decoder, row-decoder, page-buffer or the memory cell array that requires a high voltage for programming or erasing the nonvolatile memory circuit.
